(19) United States
(12) Patent Application Publication
(10) Pub. No.: US 2013/0088557 A1
(43) Pub. Date: Apr. 11, 2013

(54) THERMAL HEAD AND METHOD OF MANUFACTURING THE SAME, AND THERMAL PRINTER

(71) Applicant: Seiko Instruments Inc., Chiba-shi (JP)

(72) Inventors: Toshimitsu MOROOKA, Chiba-shi (JP); Keitaro KOROISHI, Chiba-shi (JP); Noriyoshi SHOJI, Chiba-shi (JP); Norimitsu SANBONGI, Chiba-shi (JP)

(73) Assignee: SEIKO INSTRUMENTS INC., Chiba-shi (JP)

(21) Appl. No.: 13/644,732

(22) Filed: Oct. 4, 2012

(30) Foreign Application Priority Data
Oct. 6, 2011 (JP) 2011-222185

(51) Int. Cl. B41J 2/335; H05K 13/00

(52) U.S. Cl. 347/206; 29/611

(57) ABSTRACT

The thermal head includes a support substrate, a glaze layer, heating resistors provided on the surface of the glaze layer, and a pair of electrode portions formed on the surface of the heating resistor. Each of the pair of electrode portions includes a thick electrode portion and a thin electrode portion. The thick electrode portion includes a flat surface having a thickness h1 and an inclined surface which is provided from the flat surface toward the center C of the surface of the heating resistor. The thin electrode portion has a thickness h2 smaller than the thickness h1, and is formed so as to cover the thick electrode portion.

### RELATED APPLICATIONS

This application claims priority under 35 U.S.C. §119 to Japanese Patent Application No. 2011-222185 filed on Oct. 6, 2011, the entire content of which is hereby incorporated by reference.

### BACKGROUND OF THE INVENTION

1. Field of the Invention

The present invention relates to a thermal head and a method of manufacturing the same, and a thermal printer.

2. Description of the Related Art

There has been conventionally known a thermal head for use in thermal printers, which performs printing on a thermal recording medium such as thermal paper by selectively driving a plurality of heating elements based on printing data (see, for example, Japanese Patent Application Laid-open No. 2002-36614). The heating element of the thermal head includes a heating resistor and electrodes for supplying power to the heating resistor, and the pair of electrodes is connected to both sides of the heating resistor.

In order to increase printing efficiency of the thermal head, it is desired to reduce the ratio of a wiring resistance value of the electrode to a resistance value of the heating resistor and thereby reduce a power loss in the electrode. When the thickness of the electrode is increased, the ratio of the wiring resistance value of the electrode to the resistance value of the heating resistor can be reduced. However, when the thickness of the electrode is increased, a step is defined between the heating resistor and the electrode at a distal end portion of the electrode. As a countermeasure, conventionally, the thickness of the pair of electrodes formed on the surface of the heating resistor is reduced in a region from each distal end of the electrodes by a predetermined distance as compared with other regions, to thereby prevent the reduction in heat transfer efficiency and improve the printing efficiency.

In the case presented above, after a thick electrode portion having a large electrode thickness is formed, a thin electrode portion having a small electrode thickness is formed so as to cover the thick electrode portion. However, the thick electrode portion has a uniform thickness up to its distal end, and hence the cross-sectional shape of the distal end has a substantially right angle. Further, the thickness of the thin electrode portion is smaller than the thickness of the thick electrode portion, and hence a step disconnection or a burr occurs in the thin electrode portion at the distal end portion of the thick electrode portion. Therefore, there is a high possibility of such a failure that the thin electrode portion is not formed as a continuous film but is discontinued at the distal end portion of the thick electrode portion.

### SUMMARY OF THE INVENTION

According to a first exemplary embodiment of the present invention, there is provided a thermal head, including: a support substrate; a heat storage layer formed on a front surface of the support substrate; a heating resistor provided on a surface of the heat storage layer; and a pair of electrodes formed on a surface of the heating resistor, in which each of the pair of electrodes includes: a thick electrode portion including a flat surface having a first thickness and an inclined surface which is provided from the flat surface toward a center of the surface of the heating resistor and whose thickness is gradually reduced toward the center; and a thin electrode portion which has a second thickness smaller than the first thickness and is formed so as to cover the thick electrode portion, with a distal end position of the thin electrode portion being closer to the center of the surface of the heating resistor with respect to the inclined surface.

According to the first exemplary embodiment of the present invention, the thick electrode portion includes the inclined surface which is provided from the flat surface toward the center of the surface of the heating resistor and whose thickness is gradually reduced toward the center, and the thin electrode portion is formed so as to cover the thick electrode portion. Accordingly, a disconnection or a burr is prevented from occurring in the thin electrode portion at the distal end position of the thick electrode portion, and hence the thin electrode portion is formed as a continuous film. Therefore, the uniform thin electrode portion having a continuously connected surface and having no locally-high resistance portion is formed, and hence the printing durability of the thermal head is improved.

In addition, a protective film formed on the pair of electrodes is also formed as a continuous film, and the protective film protects the heating resistor and the pair of electrodes, and hence the printing durability of the thermal head is improved. Further, the protective film is formed on the thin electrode portion which is formed as a continuous film, and hence it is possible to prevent the occurrence of problems such as the disconnection in the protective film, the separation between the protective film and the electrodes caused by the disconnection, and the intrusion of corrosive ions or the like from the disconnected portion. In this way, the printing durability of the thermal head is improved.

Further, the thin electrode portion is formed so as to cover the thick electrode portion, with its distal end position being closer to the center of the surface of the heating resistor with respect to the inclined surface. Accordingly, a step between the electrode and the heating resistor at the distal end position of the electrode is reduced to improve contact performance between the thermal paper and the region above the heating resistor, to thereby improve the transfer efficiency of heat from the heating resistor to the thermal paper. Further, this structure has an effect of preventing the heat generated by the heating resistor from diffusing via the electrode. Therefore, the printing efficiency of the thermal head is improved.

In the above-mentioned exemplary embodiment, a concave portion may be formed in the front surface of the support substrate in a region opposed to the heating resistor.

With this configuration, a cavity portion is formed between the support substrate and the heat storage layer. The cavity portion is provided at a position corresponding to the position of the surface of the heating resistor at which the pair of electrodes is not formed, and functions as a heat insulating layer for insulating heat generated from the heating resistor. Therefore, the heat generated by the heating resistor can be prevented from transferring to the support substrate via the heat storage layer and diffusing. In this way, the printing efficiency of the thermal head is improved.

Further, in the above-mentioned exemplary embodiment, the inclined surface may be formed into a tapered shape in which the thickness of the thick electrode portion is gradually reduced at a uniform slope.

Further, in the above-mentioned exemplary embodiment, the inclined surface of the thick electrode portion may be provided along a feeding direction of thermal paper to be fed by a platen roller, the platen roller being disposed so as to oppose the thermal head, and an end portion of the thick electrode portion in a direction orthogonal to the feeding direction may have a cross section having a substantially right angle.

With this configuration, regarding the direction orthogonal to the feeding direction of the thermal paper, it is not necessary to use an etchant which is adjusted for forming the inclined surface. Therefore, there is an advantage in that the manufacturing of the thermal head becomes easier. Further, the electrode portion whose cross section has a substantially right angle can be provided at the end portion of the thick electrode portion in the direction orthogonal to the feeding direction of the thermal paper, and hence it is possible to form fine electrode wiring.

Further, in the above-mentioned exemplary embodiment, the inclined surface may be formed into a stepped shape in which the thickness of the thick electrode portion is reduced in a stepwise manner, and the stepped shape may include steps having a thickness equal to or smaller than the second thickness.

Further, in the above-mentioned exemplary embodiment, the inclined surface and the surface of the heating resistor may form an angle of 45° or less.

With this configuration, the thin electrode portion is formed as a continuous film more reliably, and hence the durability and the printing efficiency of the thermal head are improved.

According to a second exemplary embodiment of the present invention, there is provided a method of manufacturing a thermal head, including: a heat storage layer forming step of forming a heat storage layer on a front surface of a support substrate; a resistor forming step of forming a heating resistor on a surface of the heat storage layer formed in the heat storage layer forming step; a first electrode forming step of forming a pair of thick electrode portions on a surface of the heating resistor formed in the resistor forming step, the pair of thick electrode portions each including a flat surface having a first thickness and an inclined surface which is provided from the flat surface toward a center of the surface of the heating resistor and whose thickness is gradually reduced toward the center; and a second electrode forming step of forming a pair of thin electrode portions having a second thickness smaller than the first thickness, so as to cover the pair of thick electrode portions, with a distal end position of each of the pair of thin electrode portions being closer to the center of the surface of the heating resistor with respect to the inclined surface.

According to the second exemplary embodiment of the present invention, the pair of thick electrode portions each including the inclined surface which is provided from the flat surface toward the center of the surface of the heating resistor and whose thickness is gradually reduced toward the center is formed, and the thin electrode portions are formed so as to cover the thick electrode portions. Accordingly, a disconnection or a burr is prevented from occurring in the thin electrode portion at the distal end position of the thick electrode portion, and hence the thin electrode portion is formed as a continuous film. Therefore, the uniform thin electrode portion having a continuously connected surface and having no locally-high resistance portion is formed, and hence the printing durability of the thermal head is improved.

In addition, the protective film formed on the pair of electrodes is also formed as a continuous film, and the protective film protects the heating resistor and the pair of electrodes, and hence the printing durability of the thermal head is improved. Further, the protective film is formed on the thin electrode portion which is formed as a continuous film, and hence it is possible to prevent the occurrence of problems such as the disconnection in the protective film, the separation between the protective film and the electrodes caused by the disconnection, and the intrusion of corrosive ions or the like from the disconnected portion. In this way, the printing durability of the thermal head is improved.

Further, the thin electrode portion is formed so that its distal end position is closer to the center of the surface of the heating resistor with respect to the inclined surface. Accordingly, a step between the electrode portion and the heating resistor at the distal end position of the electrode portion is reduced to improve contact performance between the printing paper and the region above the heating resistor, to thereby improve the transfer efficiency of heat from the heating resistor to the paper. Further, this structure has an effect of preventing the heat generated by the heating resistor from diffusing via the electrode. Therefore, the printing efficiency of the thermal head is improved.

According to the present invention, the thermal head having improved printing durability and improved printing efficiency, the method of manufacturing the thermal head, and the thermal printer can be provided.

### BRIEF DESCRIPTION OF THE DRAWINGS

In the accompanying drawings:

FIG. 1 is a schematic structural view of a thermal printer according to a first embodiment of the present invention;

FIG. 2 is a plan view of a thermal head of FIG. 1 viewed from a protective film side;

FIG. 3 is a cross-sectional view taken along the arrow A-A of a portion of a heating resistor of the thermal head of FIG. 2;

FIG. 4 is a flowchart illustrating a method of manufacturing the thermal head of FIG. 2;

FIG. 5 is a flowchart illustrating details of a first electrode forming step of FIG. 4;

FIG. 6 is a flowchart illustrating details of a second electrode forming step of FIG. 4;

FIGS. 7A to 7E are cross-sectional views taken along the arrow A-A of the portion of the heating resistor and illustrate the states in the course of manufacturing the thermal head of FIG. 2, in which FIG. 7A illustrates the state in the first electrode forming step; FIG. 7B, the state in the second electrode forming step (thin electrode layer forming step); FIG. 7C, the state in the second electrode forming step (thin electrode layer removing step); FIG. 7D, the state in the second electrode forming step (resist mask for thin electrode pattern removing step); and FIG. 7E, the state in a protective film forming step;

FIGS. 8A to 8C are plan views illustrating the states in the course of manufacturing the thermal head of FIG. 2, in which FIG. 8A illustrates the state in the first electrode forming step; FIG. 8B, the state in the second electrode forming step (thin electrode layer removing step); and FIG. 8C, the state in the second electrode forming step (resist mask for thin electrode pattern removing step);

FIGS. 9A and 9B are plan views illustrating the states in the course of manufacturing the thermal head of FIG. 2, in which FIG. 9A illustrates the state in the second electrode forming step (thin electrode layer forming step), and FIG. 9B illustrates the state in the protective film forming step;

FIGS. 10A to 10C are plan views illustrating the states in the course of manufacturing the thermal head of FIG. 2, in which FIG. 10A illustrates the state in the first electrode forming step; FIG. 10B, the state in the second electrode forming step (thin electrode layer removing step); and FIG. 10C, the state in the second electrode forming step (resist mask for thin electrode pattern removing step);

FIG. 11 is a cross-sectional view taken along the arrow A-A of a portion of a heating resistor in a thermal head in which a cavity portion is provided;

FIG. 12 is a cross-sectional view taken along the arrow A-A of a portion of a heating resistor in a thermal head including an electrode portion having an inclined surface having a stepped shape; and

FIG. 13 is a flowchart illustrating a method of manufacturing the thermal head of FIG. 11.

### DETAILED DESCRIPTION OF THE PREFERRED EMBODIMENTS

### First Embodiment

A thermal head according to a first embodiment of the present invention is described with reference to the accompanying drawings.

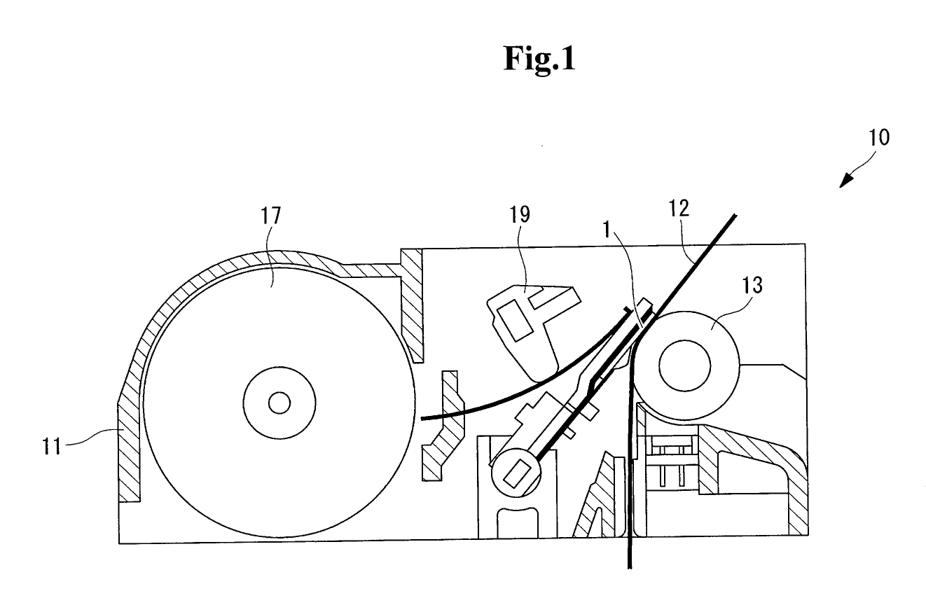

A thermal head 1 according to this embodiment is used for a thermal printer 10 as illustrated in FIG. 1. The thermal printer 10 performs printing on an object to be printed, such as thermal paper 12, by selectively driving a plurality of heating resistor elements included in the thermal head 1 based on printing data.

The thermal printer 10 includes a main body frame 11, a platen roller 13 disposed with its central axis being horizontal, the thermal head 1 disposed opposite to an outer peripheral surface of the platen roller 13, and a heat dissipation plate (not shown) supporting the thermal head 1. The thermal printer 10 further includes a paper feeding mechanism 17 for feeding the thermal paper 12 between the platen roller 13 and the thermal head 1, and a pressure mechanism 19 for pressing the thermal head 1 against the thermal paper 12 with a predetermined pressing force.

Against the platen roller 13, the thermal head 1 is pressed via the thermal paper 12 by the operation of the pressure mechanism 19. Accordingly, a reaction force of the platen roller 13 is applied to the thermal head via the thermal paper 12.

The heat dissipation plate is a plate-shaped member made of a metal such as aluminum, a resin, ceramics, glass, or the like, and serves for fixation and heat dissipation of the thermal head 1.

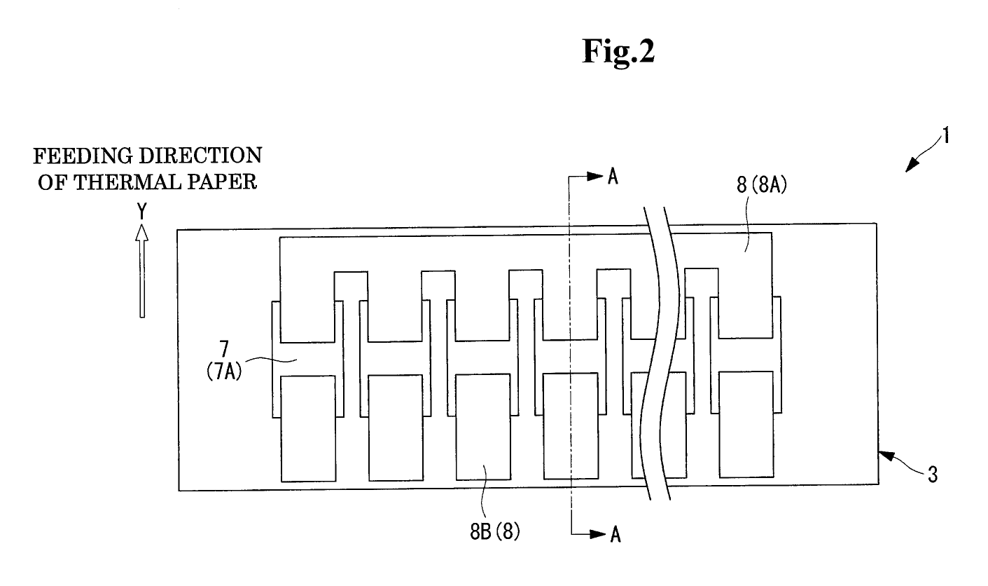

As illustrated in FIG. 2, the thermal head 1 includes a plurality of heating resistors 7 and a plurality of electrode portions 8 which are arrayed in a longitudinal direction of a rectangular support substrate 3. The arrow Y represents a feeding direction of the thermal paper 12 by the paper feeding mechanism 17.

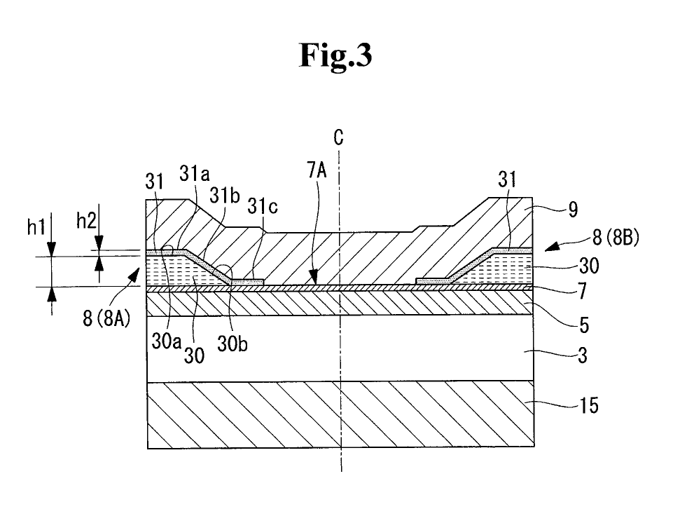

FIG. 3 illustrates a cross section taken along the arrow A-A of the portion of the heating resistor 7 of FIG. 2. The thermal head 1 according to one embodiment of the present invention includes the support substrate 3, a glaze layer 5 formed on an upper end surface (front surface) of the support substrate 3, the heating resistors 7 provided on the glaze layer 5, a pair of electrode portions 8 provided on both sides of the heating resistor 7, and a protective film 9 for covering the heating resistors 7 and the electrode portions 8 to protect the heating resistors 7 and the electrode portions 8 from abrasion and corrosion. Each of the pair of electrode portions 8 of the thermal head 1 includes a thick electrode portion 30 and a thin electrode portion 31. The thick electrode portion 30 includes a flat surface 30a having a thickness h1 and an inclined surface 30b which is provided from the flat surface 30a toward the center C of the surface of the heating resistor 7 and whose thickness is gradually reduced toward the center C. The thin electrode portion 31 has a thickness h2 smaller than the thickness h1 and is formed so as to cover the thick electrode portion 30, with its distal end position being closer to the center C of the surface of the heating resistor 7 with respect to the inclined surface 30b.

The support substrate 3 is, for example, an insulating substrate such as a glass substrate or a silicon substrate having a thickness of about 300 μm to about 1 mm. In this case, as the support substrate 3, a ceramic plate having an alumina component of 99.5% is used. The glaze layer 5 is made of, for example, a glass material having a thickness of about 10 μm to about 100 μm, and functions as a heat storage layer for storing heat generated from the heating resistors 7.

As illustrated in FIG. 2, the plurality of heating resistors 7 are arrayed on the upper surface of the glaze layer 5 at predetermined intervals in the longitudinal direction of the support substrate 3. The heating resistor 7 is formed of, for example, a Ta—N film or a Ta—SiO₂ film whose main component is tantalum (Ta). A specific method of forming the heating resistor 7 is described later.

The electrode portion 8 causes the heating resistor 7 to generate heat. As illustrated in FIG. 2, the electrode portion 8 includes a common electrode 8A connected to one end of each of the heating resistors 7 in a direction orthogonal to the array direction of the heating resistors 7, and individual electrodes 8B connected to another end of each of the heating resistors 7. The common electrode 8A is integrally connected to all the heating resistors 7, and the individual electrodes 8B are connected to each of the heating resistors 7.

When voltage is selectively applied to the individual electrodes 8B, current flows through the heating resistors 7 which are connected to the selected individual electrodes 8B and the common electrode 8A opposed thereto, to thereby allow the heating resistors 7 to generate heat. In this state, the pressure mechanism 19 operates to press the thermal paper 12 against a surface portion (printing portion) of the protective film 9 covering the heating portions of the heating resistors 7, and then color is developed on the thermal paper 12 to be printed.

As illustrated in FIG. 3, the common electrode 8A and the individual electrodes 8B each include the thick electrode portion 30 and the thin electrode portion 31. The thick electrode portion 30 includes the flat surface 30a having the thickness h1 and the inclined surface 30b which is provided from the flat surface 30a toward the center C of the surface of the heating resistor 7 and which has a tapered shape whose thickness is gradually reduced at a uniform slope toward the center C. The thick electrode portion 30 is formed of an Al film, an Al—Si film, or an Al—Si—Cu film whose main component is Al, and the thickness h1 is set to 1 μm to 3 μm. The thin electrode portion 31 has the thickness h2 smaller than the thickness h1 and is formed so as to cover the thick electrode portion 30, with its distal end position being closer to the center C of the surface of the heating resistor 7 with respect to the inclined surface 30b.

The thin electrode portion 31 is made of the same material as that of the thick electrode portion 30, and the thickness h2 is set to 0.1 μm to 0.5 μm. The thin electrode portion 31 includes a base end portion 31a formed in a region corresponding to the flat surface 30a of the thick electrode portion 30, an inclined portion 31b formed in a region corresponding to the inclined surface 30b, and a distal end portion 31c formed in a region corresponding to the surface of the heating resistor 7. Those portions are formed as a continuous film.

Next, a method of manufacturing the thermal head 1 having the above-mentioned configuration is described below.

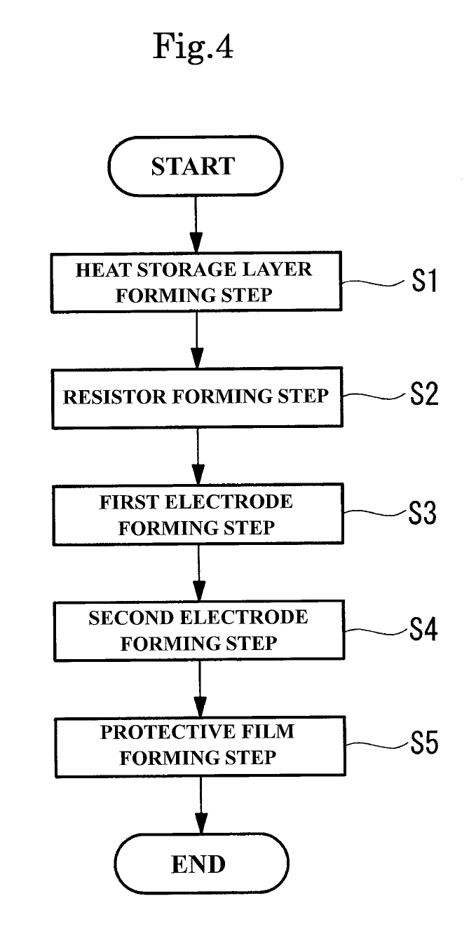

As illustrated in FIG. 4, the method of manufacturing the thermal head 1 according to this embodiment includes a heat storage layer forming step S1 of forming the glaze layer 5 functioning as a heat storage layer on the front surface of the support substrate 3, a resistor forming step S2 of forming the heating resistors 7 on the surface of the glaze layer 5, a first electrode forming step S3 of forming, on the surface of the heating resistor 7, a pair of thick electrode portions 30 each including the flat surface 30a having the thickness h1 and the inclined surface 30b which is provided from the flat surface 30a toward the center C of the surface of the heating resistor 7 and whose thickness is gradually reduced toward the center C, a second electrode forming step S4 of forming a pair of thin electrode portions 31 having the thickness h2 so as to cover the thick electrode portions 30, and a protective film forming step S5 of forming the protective film 9 so as to cover the surface of the heating resistors 7 and the pairs of electrodes 8 formed on the surface of the heating resistors 7. The steps of the method of manufacturing the thermal head 1 are hereinafter described in detail.

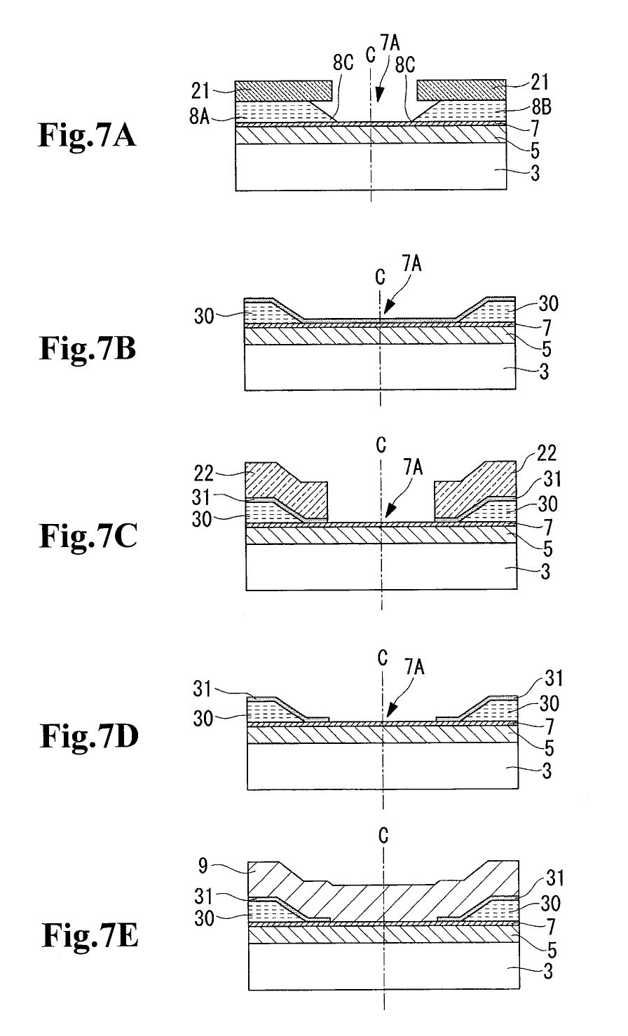

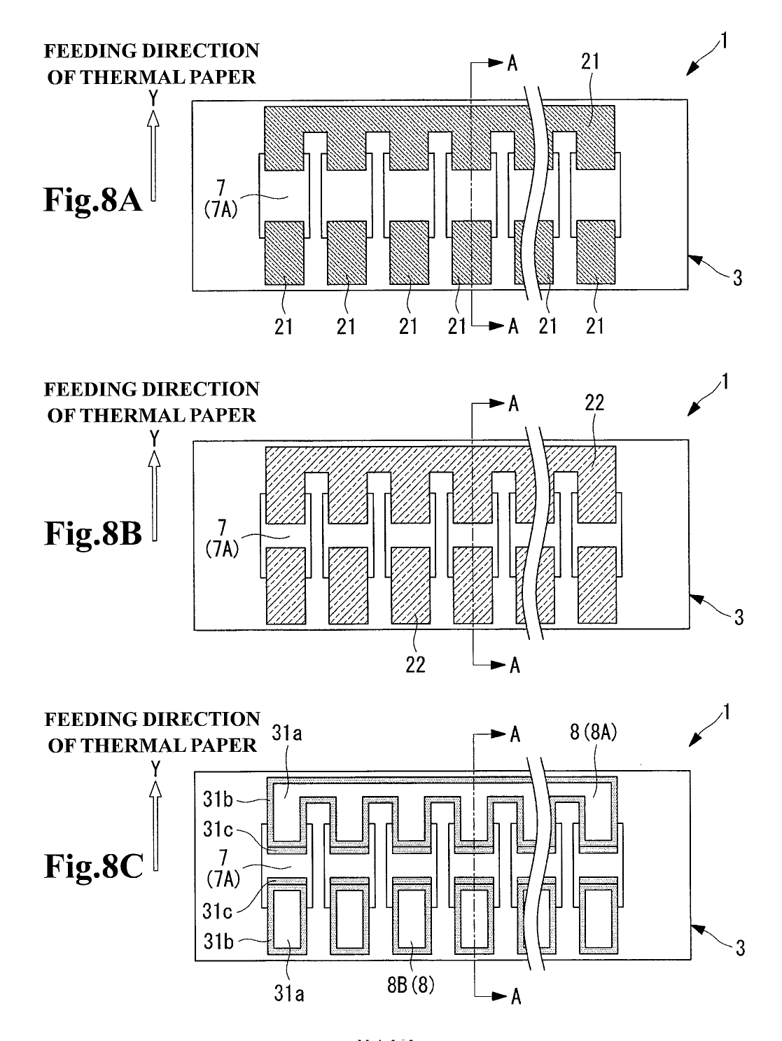

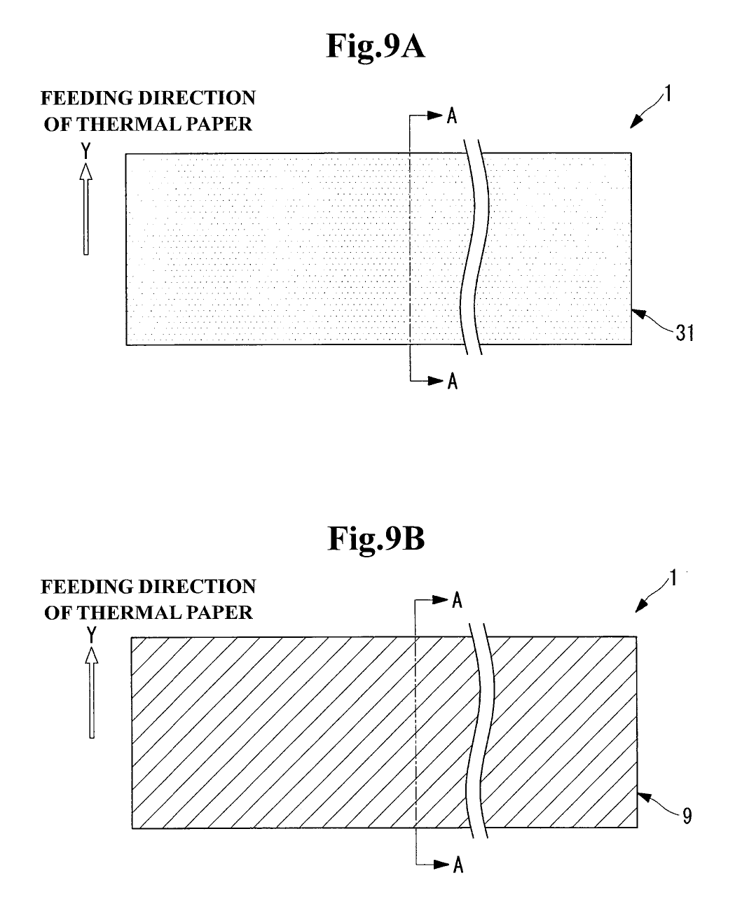

In the following description, FIGS. 7A to 7E are views taken along the arrow A-A of the portion of the heating resistor and illustrate the states in the course of manufacturing the thermal head of FIG. 2. FIG. 7A illustrates the state in the first electrode forming step, FIG. 7B illustrates the state in the second electrode forming step (thin electrode layer forming step), FIG. 7C illustrates the state in the second electrode forming step (thin electrode layer removing step), FIG. 7D illustrates the state in the second electrode forming step (resist mask for thin electrode pattern removing step), and FIG. 7E illustrates the state in the protective film forming step. FIGS. 8A to 8C are plan views illustrating the states in the course of manufacturing the thermal head 1 of FIG. 2. FIG. 8A illustrates the state in the first electrode forming step, FIG. 8B illustrates the state in the second electrode forming step (thin electrode layer removing step), and FIG. 8C illustrates the state in the second electrode forming step (resist mask for thin electrode pattern removing step). FIGS. 9A and 9B are plan views illustrating the states in the course of manufacturing the thermal head 1 of FIG. 2. FIG. 9A illustrates the state in the second electrode forming step (thin electrode layer forming step), and FIG. 9B illustrates the state in the protective film forming step.

In the heat storage layer forming step S1, a glaze of a glass material is applied on an upper end surface (front surface) of the support substrate 3, to thereby form the glaze layer 5.

In the resistor forming step S2, by sputtering, a heating resistor material whose main component is tantalum (Ta) such as a Ta—N film or a Ta—SiO₂ film is formed on the entire surface of the glaze layer 5 so as to have a uniform thickness of 0.1 μm to 0.5 μm. After that, photolithography is used to form a resist mask for heating resistor pattern, and then etching is performed to form the heating resistors 7 on the glaze layer 5. The plurality of heating resistors 7 are formed at predetermined intervals in the longitudinal direction of the support substrate 3.

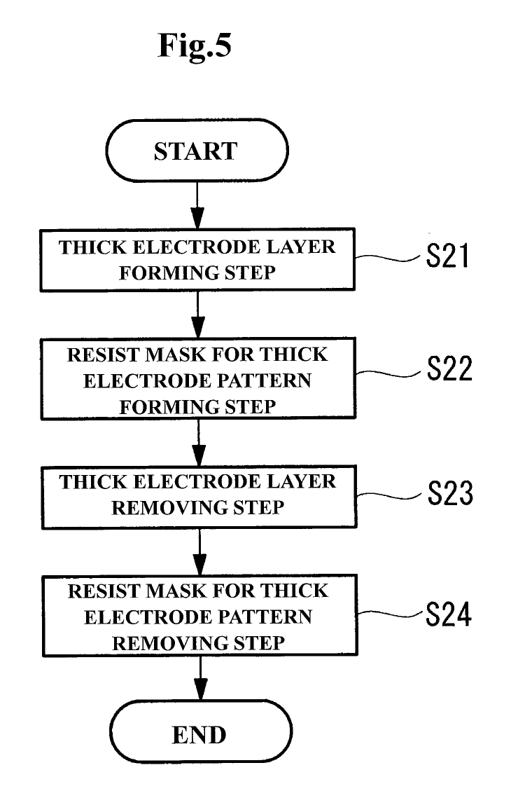

As illustrated in FIG. 5, the first electrode forming step S3 includes, as sub-steps, a thick electrode layer forming step S21 of forming a thick electrode layer on the glaze layer 5, a resist mask for thick electrode pattern forming step S22 of forming resist masks for thick electrode pattern 21 on the thick electrode layer on both sides of a heating portion 7A with a space therebetween, a thick electrode layer removing step S23 of removing regions of the thick electrode layer which are not covered by the resist masks for thick electrode pattern 21 by performing etching processing using a permeable solvent, and a resist mask for thick electrode pattern removing step S24 of removing the resist masks for thick electrode pattern 21.

In the thick electrode layer forming step S21, as an electrode material for supplying power to the heating resistors 7, the thick electrode layer formed of an Al film, an Al—Si film, or an Al—Si—Cu film whose main component is Al is formed by sputtering or the like on the glaze layer 5 so as to have the thickness h1 of 1 μm to 3 μm.

In the resist mask for thick electrode pattern forming step S22, as illustrated in FIG. 7A and FIG. 8A, photoresists are applied onto the thick electrode layer on both sides of the heating portion 7A, and the photoresists are exposed and developed with the use of a photomask, to thereby form the resist masks for thick electrode pattern 21 across the heating portion 7A (with a space therebetween).

In the thick electrode layer removing step S23, etching processing is performed with the use of an etchant, such as a mixed acid solution of phosphoric acid, acetic acid, or nitric acid and pure water or the like, whose adhesiveness with the photoresist is adjusted by the mixture ratio. For example, when the mixture ratio of nitric acid is increased, the solubility of the photoresist to the etchant is enhanced. As a result, the adhesiveness of the photoresist becomes lower as the etching progresses. In this case, if the etchant having low adhesiveness is used to etch the Al film (electrode layer), the etchant enters the interface between the resist mask for thick electrode pattern 21 and the Al film simultaneously with the etching of Al. Then, the etching progresses also in the direction along the surface of the thick electrode layer.

Through appropriate adjustment of the etching rate in the direction along the surface of the thick electrode layer and the thickness direction, at the end of the etching, the flat surface 30a having the thickness h1 and the inclined surface 30b which is provided from the flat surface 30a toward the center C of the surface of the heating resistor 7 and whose thickness is gradually reduced toward the center C can be formed in the thick electrode layer. Further, as illustrated in FIG. 8C, the inclined surface 30b is formed not only in the longitudinal direction of the heating resistor 7 but also in the lateral direction orthogonal to the longitudinal direction of the heating resistor 7 similarly.

Note that, it is preferred that the inclined surface 30b be formed at an angle of 3° or more and 45° or less with respect to the surface of the glaze layer 5. It is more preferred that the inclined surface 30b be formed at an angle of 3° or more and 30° or less with respect to the surface of the glaze layer. With such an inclination angle, the thin electrode portion 31 is formed on the thick electrode portion 30 as a continuous film, and hence the durability and the printing efficiency of the thermal head 1 are improved. Further, when the inclined surface 30b has an angle of 3° or more and 45° or less, the durability with respect to a pressure force and a frictional force applied by the platen roller 13 or the thermal paper 12 to the thermal head 1 can be increased.

In the resist mask for thick electrode pattern removing step S24, the resist mask for thick electrode pattern 21 is removed with the use of a stripper such as an organic solvent, to thereby expose the thick electrode portion 30 having the inclined surface 30b formed therein.

As described above, in the first electrode forming step S3, as the sub-steps, the thick electrode layer forming step S21, the resist mask for thick electrode pattern forming step S22, the thick electrode layer removing step S23, and the resist mask for thick electrode pattern removing step S24 are performed, to thereby form the thick electrode portions 30.

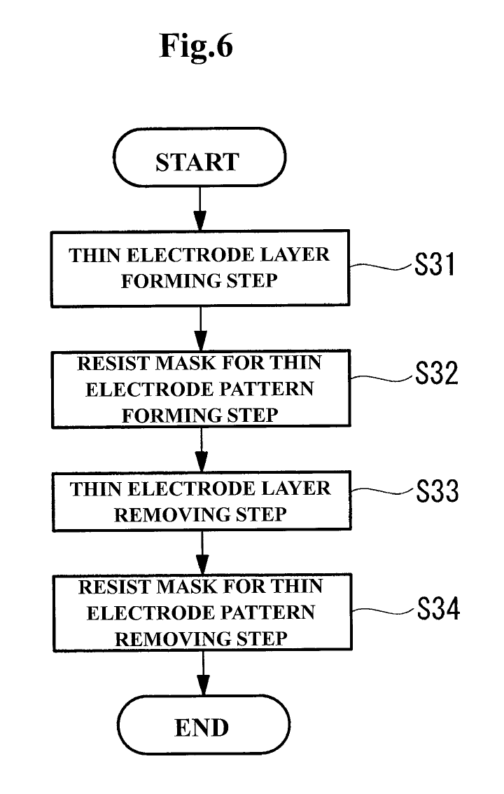

As illustrated in FIG. 6, the second electrode forming step S4 includes, as sub-steps, a thin electrode layer forming step S31 of forming a thin electrode layer on the thick electrode portion 30 and the heating resistor 7, a resist mask for thin electrode pattern forming step S32 of forming resist masks for thin electrode pattern 22 on the thin electrode layer on both sides of the heating portion with a space therebetween, a thin electrode layer removing step S33 of removing regions of the thin electrode layer which are not covered by the resist masks for thin electrode pattern 22 by performing etching processing using a permeable solvent, and a resist mask for thin electrode pattern removing step S34 of removing the resist masks for thin electrode pattern 22.

In the thin electrode layer forming step S31, as illustrated in FIG. 7B and FIG. 9A, as an electrode material for supplying power to the heating resistors 7, the thin electrode layer formed of an Al film, an Al—Si film, or an Al—Si—Cu film whose main component is Al is formed by sputtering or the like on the glaze layer 5 so as to have the uniform thickness h2 of 0.1 μm to 0.5 μm.

In the resist mask for thin electrode pattern forming step S32, photoresists are applied onto the thin electrode layer on both sides of the heating portion 7A, and the photoresists are exposed and developed with the use of a photomask, to thereby form the resist masks for thin electrode pattern 22 across the heating portion 7A (with a space therebetween).

In the thin electrode layer removing step S33, etching processing is performed with the use of an etchant, such as a mixed acid solution of phosphoric acid, acetic acid, or nitric acid and pure water or the like, whose adhesiveness with the photoresist is adjusted by the mixture ratio. In the step S33, only the thin electrode layer having a small thickness is removed. The thin electrode layer is very thin as compared to the thick electrode layer, and hence it is unnecessary to form a gently inclined surface at its end portion. Therefore, in the step S33, in addition to the etchant used in the thick electrode layer removing step S23, an etchant having a lower mixture ratio of nitric acid than the etchant used in the thick electrode layer removing step S23 can also be used. This etching processing removes the resist mask for thin electrode pattern 22 on the heating portion 7A. Then, the states illustrated in FIG. 7C and FIG. 8B are obtained.

In the resist mask for thin electrode pattern removing step S34, as illustrated in FIG. 7D and FIG. 8C, the resist mask 22 for thin electrode pattern is removed with the use of a stripper such as an organic solvent, to thereby expose the thin electrode portion 31. As illustrated in FIG. 8C, the exposed thin electrode portion 31 includes the base end portion 31a formed in the region corresponding to the flat surface 30a of the thick electrode portion 30, the inclined portion 31b formed in the region corresponding to the inclined surface 30b, and the distal end portion 31c formed in the region corresponding to the surface of the heating resistor 7. Those portions are formed as a continuous film.

As described above, in the second electrode forming step S4, as the sub-steps, the thin electrode layer forming step S31, the resist mask for thin electrode pattern forming step S32, the thin electrode layer removing step S33, and the resist mask for thin electrode pattern removing step S34 are performed, to thereby form the thin electrode portions 31.

In the protective film forming step S5, as illustrated in FIG. 7E and FIG. 9B, in order to prevent oxidation and abrasion of the heating resistors 7 and the electrode portions 8, a mixed film of Si₃N₄ and SiO₂ is formed by sputtering or the like at a thickness of about 3 μm to about 6 μm so as to cover the heating resistors 7 and the electrode portions 8, to thereby form the protective film 9.

The thermal head 1 manufactured in this way according to this embodiment includes the support substrate 3, the glaze layer 5 formed on the front surface of the support substrate 3, the heating resistors 7 provided on the surface of the glaze layer 5, and the pair of electrode portions 8 formed on the surface of the heating resistor 7. Each of the pair of electrode portions 8 includes the thick electrode portion 30 and the thin electrode portion 31. The thick electrode portion 30 includes the flat surface 30a having the thickness h1 and the inclined surface 30b which is provided from the flat surface 30a toward the center C of the surface of the heating resistor 7 and whose thickness is gradually reduced toward the center C. The thin electrode portion 31 has the thickness h2 smaller than the thickness h1, and is formed so as to cover the thick electrode portion 30, with its distal end position being closer to the center C of the surface of the heating resistor 7 with respect to the inclined surface 30b. Therefore, the thermal head 1 has the following effects.

That is, according to the thermal head 1 of this embodiment, the thick electrode portion 30 includes the inclined surface 30b which is provided from the flat surface 30a toward the center C of the surface of the heating resistor 7 and whose thickness is gradually reduced toward the center C, and the thin electrode portion 31 is formed so as to cover the thick electrode portion 30. Accordingly, a disconnection or a burr is prevented from occurring in the thin electrode portion 31 at the distal end position of the thick electrode portion 30, and hence the thin electrode portion 31 is formed as a continuous film. Therefore, the uniform thin electrode portion 31 having a continuously connected surface and having no locally-high resistance portion is formed, and hence the printing durability of the thermal head 1 is improved.

In addition, the protective film 9 formed on the electrode portions 8 is also formed as a continuous film, and the protective film 9 protects the heating resistors 7 and the pairs of electrode portions 8, and hence the printing durability of the thermal head 1 is improved. Further, the protective film 9 is formed on the thin electrode portion 31 which is formed as a continuous film, and hence it is possible to prevent the occurrence of problems such as the disconnection in the protective film 9, the separation between the protective film 9 and the electrode portions 8 caused by the disconnection, and the intrusion of corrosive ions or the like from the disconnected portion. In this way, the printing durability of the thermal head 1 is improved.

Further, the thin electrode portion 31 is formed so as to cover the thick electrode portion 30, with its distal end position being closer to the center C of the surface of the heating resistor 7 with respect to the inclined surface 30a. Accordingly, a step between the electrode portion 8 and the heating resistor 7 at the distal end position of the electrode portion 8 is reduced to improve contact performance between the thermal paper and the region above the heating resistor 7, to thereby improve the transfer efficiency of heat from the heating resistor 7 to the thermal paper. Therefore, the printing efficiency of the thermal head 1 is improved.

Further, in the thermal head 1 according to this embodiment, the angle formed by the inclined surface 30b and the surface of the heating resistor 7 is 45° or less, and hence the thin electrode portion 31 is formed as a continuous film. Therefore, the durability and the printing efficiency of the thermal head 1 are improved.

### Second Embodiment

Next, a thermal head according to a second embodiment of the present invention is described with reference to the accompanying drawings.

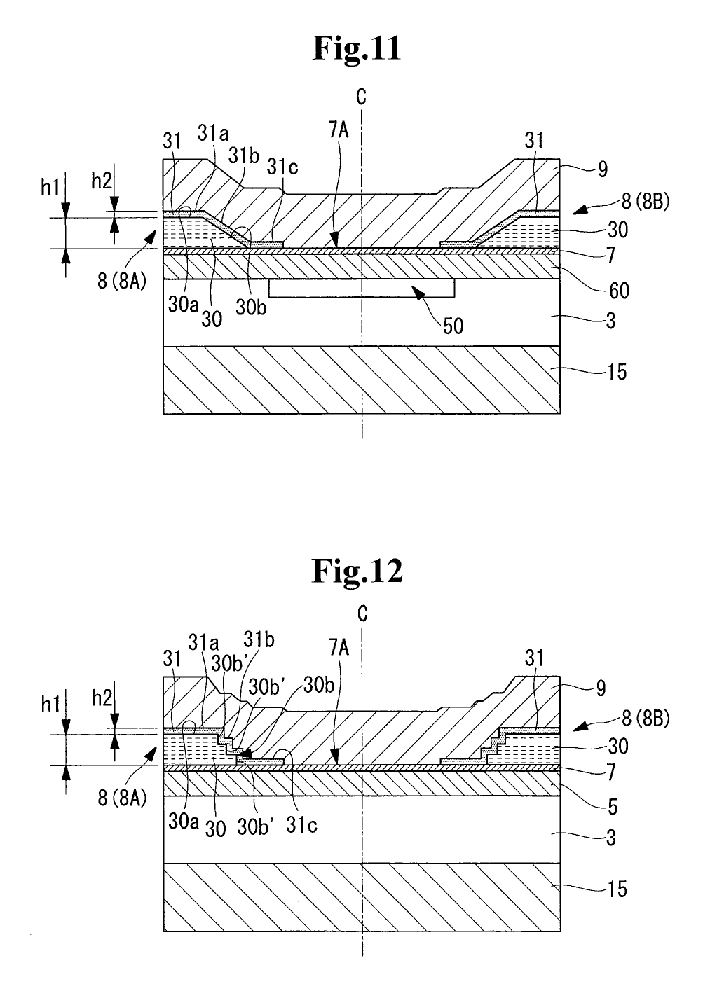

As the shape of the support substrate 3 included in the thermal head 1, the first embodiment adopts a flat plate shape as illustrated in FIG. 3. On the other hand, the second embodiment adopts a shape in which a concave portion is provided in the support substrate 3. FIG. 11 is a cross-sectional view taken along the arrow A-A of the portion of the heating resistor 7 in the thermal head 1. In the upper end surface (front surface) of the support substrate 3, a rectangular concave portion 50 extending in the longitudinal direction of the support substrate 3 is provided. The concave portion 50 is covered by an upper substrate 60, to thereby form a cavity portion between the upper substrate 60 and the support substrate 3.

The support substrate 3 is, for example, an insulating substrate such as a glass substrate or a silicon substrate having a thickness of about 300 μm to about 1 mm. In this case, as the support substrate 3, the glass substrate is used. The upper substrate 60 is made of, for example, a glass material having a thickness of about 10 μm to about 100 μm, and functions as a heat storage layer for storing heat generated from the heating resistors 7.

Note that, the configuration of the thermal head 1 according to the second embodiment is the same as in the thermal head 1 according to the first embodiment except for the support substrate 3 and the upper substrate 60, and hence description thereof is omitted.

The cavity portion formed between the upper substrate 60 and the support substrate 3 has a communication structure opposed to all the heating resistors 7. The cavity portion functions as a hollow heat insulating layer for preventing the heat, which is generated from the heating resistors 7, from transferring from the upper substrate 60 to the support substrate 3. Because the cavity portion functions as the hollow heat insulating layer, an amount of heat, which transfers to the above of the heating resistors 7 and is used for printing and the like, can be increased to be more than an amount of heat, which transfers to the support substrate 3 via the upper substrate 60 located under the heating resistors 7. Therefore, the heat generated by the heating resistors 7 can be prevented from transferring to the support substrate 3 via the upper substrate 60 and diffusing. In this way, the printing efficiency of the thermal head 1 is improved.

Next, a method of manufacturing the thermal head 1 according to the second embodiment is described below.

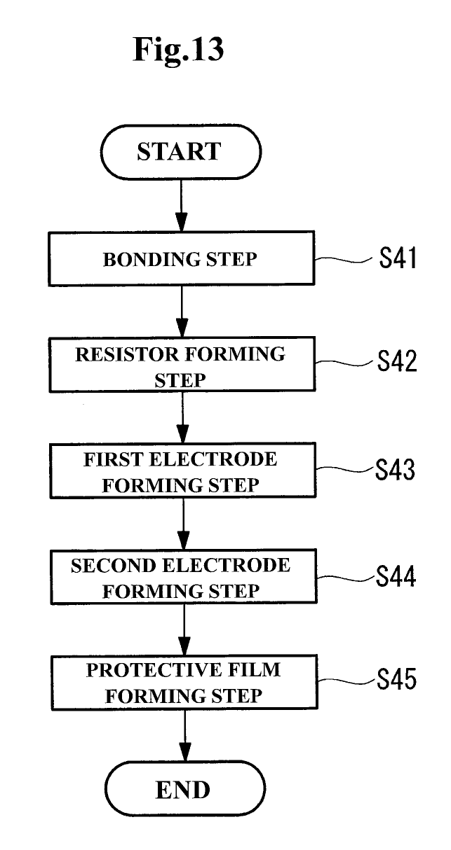

As illustrated in FIG. 13, the method of manufacturing the thermal head 1 according to this embodiment includes a bonding step S41 of bonding the rear surface of the upper substrate 60 on the front surface of the support substrate 3 in a stacked state, a resistor forming step S42 of forming the heating resistors 7 on the surface of the upper substrate 60, a first electrode forming step S43 of forming, on the surface of the heating resistor 7, the pair of thick electrode portions 30 each including the flat surface 30a having the thickness h1 and the inclined surface 30b which is provided from the flat surface 30a toward the center C of the surface of the heating resistor 7 and whose thickness is gradually reduced toward the center C, a second electrode forming step S44 of forming the pair of thin electrode portions 31 having the thickness h2 so as to cover the thick electrode portions 30, and a protective film forming step S45 of forming the protective film 9 so as to cover the surface of the heating resistors 7 and the pairs of electrodes 8 formed on the surface of the heating resistors 7. The bonding step S41 of the method of manufacturing the thermal head 1 is hereinafter described in detail. Note that, S42 to S45 of FIG. 13 are the same as S2 to S5 of FIG. 4, and hence description thereof is omitted.

In the bonding step S41, the lower end surface (rear surface) of the upper substrate 60 and the upper end surface (front surface) of the support substrate 3 are bonded to each other by high temperature fusing or anodic bonding. At this time, the support substrate 3 and the upper substrate 60 are bonded to each other in a dry state, and the substrates thus bonded to each other are subjected to heat treatment at a temperature equal to or higher than 200° C. and equal to or lower than softening points thereof, for example.

The thermal head 1 manufactured in this way according to this embodiment includes the support substrate 3, the upper substrate 60 bonded on the front surface of the support substrate 3 in a stacked state, the heating resistors 7 provided on the surface of the upper substrate 60, and the pair of electrode portions 8 formed on the surface of the heating resistor 7. Each of the pair of electrode portions 8 includes the thick electrode portion 30 and the thin electrode portion 31. The thick electrode portion 30 includes the flat surface 30a having the thickness h1 and the inclined surface 30b which is provided from the flat surface 30a toward the center C of the surface of the heating resistor 7 and whose thickness is gradually reduced toward the center C. The thin electrode portion 31 has the thickness h2 smaller than the thickness h1, and is formed so as to cover the thick electrode portion 30, with its distal end position being closer to the center C of the surface of the heating resistor 7 with respect to the inclined surface 30b. Therefore, the thermal head 1 has the following effects.

That is, according to the thermal head 1 of this embodiment, the thick electrode portion 30 includes the inclined surface 30b which is provided from the flat surface 30a toward the center C of the surface of the heating resistor 7 and whose thickness is gradually reduced toward the center C, and the thin electrode portion 31 is formed so as to cover the thick electrode portion 30. Accordingly, a disconnection or a burr is prevented from occurring in the thin electrode portion 31 at the distal end position of the thick electrode portion 30, and hence the thin electrode portion 31 is formed as a continuous film. Therefore, the uniform thin electrode portion 31 having a continuously connected surface and having no locally-high resistance portion is formed, and hence the printing durability of the thermal head 1 is improved.

In addition, the protective film 9 formed on the electrode portions 8 is also formed as a continuous film, and the protective film 9 protects the heating resistors 7 and the pairs of electrode portions 8, and hence the printing durability of the thermal head 1 is improved. Further, the protective film 9 is formed on the thin electrode portion 31 which is formed as a continuous film, and hence it is possible to prevent the occurrence of problems such as the disconnection in the protective film 9, the separation between the protective film 9 and the electrode portions 8 caused by the disconnection, and the intrusion of corrosive ions or the like from the disconnected portion. In this way, the printing durability of the thermal head 1 is improved.

Further, the thin electrode portion 31 is formed so as to cover the thick electrode portion 30, with its distal end position being closer to the center C of the surface of the heating resistor 7 with respect to the inclined surface 30a. Accordingly, a step between the electrode portion 8 and the heating resistor 7 at the distal end position of the electrode portion 8 is reduced to improve contact performance between the thermal paper and the region above the heating resistor 7, to thereby improve the transfer efficiency of heat from the heating resistor 7 to the thermal paper. Therefore, the printing efficiency of the thermal head 1 is improved.

Further, in the thermal head 1 according to this embodiment, the angle formed by the inclined surface 30b and the surface of the heating resistor 7 is 45° or less, and hence the thin electrode portion 31 is formed as a continuous film. Therefore, the durability and the printing efficiency of the thermal head 1 are improved.

Further, the thermal head 1 according to this embodiment has a configuration in which the concave portion 50 is formed in the front surface of the support substrate 3 in the region opposed to the heating resistors 7.

With this configuration, the cavity portion is formed between the support substrate 3 and the upper substrate 60. The cavity portion is provided at a position corresponding to the heating portion (the position of the surface of the heating resistor 7 at which the pair of electrode portions 8 is not formed), and functions as the heat insulating layer for insulating heat generated from the heating resistors 7. Therefore, the heat generated by the heating resistors 7 can be prevented from transferring to the support substrate 3 via the upper substrate 60 and diffusing. In this way, the printing efficiency of the thermal head 1 is improved.

Further, the thermal head according to this embodiment has a configuration in which the concave portion 50 is formed inside the position corresponding to the inclined surface 30b toward the center C of the surface of the heating resistor 7, and the distal end portion 31c of the thin electrode portion 31 of the electrode portion 8 is formed within the region opposed to the cavity portion.

With this configuration, the region of the electrode portion 8 which has a low thermal conductivity extends to the outside of the center C with respect to the region opposed to the cavity portion, and hence the heat can be prevented from diffusing from the heating resistors 7 via the electrode portion 8 in the planar direction of the upper substrate 60. In this way, the printing efficiency of the thermal head is improved.

### Other Embodiments

The first and second embodiments adopt, as the shape of the inclined surface 30b, a tapered shape in which the thickness is gradually reduced at a uniform slope from the flat surface 30a toward the center C of the surface of the heating resistor 7. However, a stepped shape in which the thickness is reduced in a stepwise manner toward the center C may be adopted. FIG. 12 is a cross-sectional view of the portion of the heating resistor taken along the arrow A-A of the thermal head, which includes an electrode portion having an inclined surface having a stepped shape. Note that, it is desired that an inclined surface 30b having a stepped shape including a plurality of steps 30b′ be formed so that an average inclination angle of the inclined surface 30b may be 3° or more and 45° or less with respect to the surface of the heating resistor 7. Further, it is more desired that the steps of the inclined surface 30b having the stepped shape be formed so that an average inclination angle of the inclined surface 30b may be 3° or more and 30° or less with respect to the surface of the heating resistor 7. Note that, it is desired that each step 30b′ of the inclined surface 30b be equal to or smaller than the thickness h2 of the thin electrode portion 31.

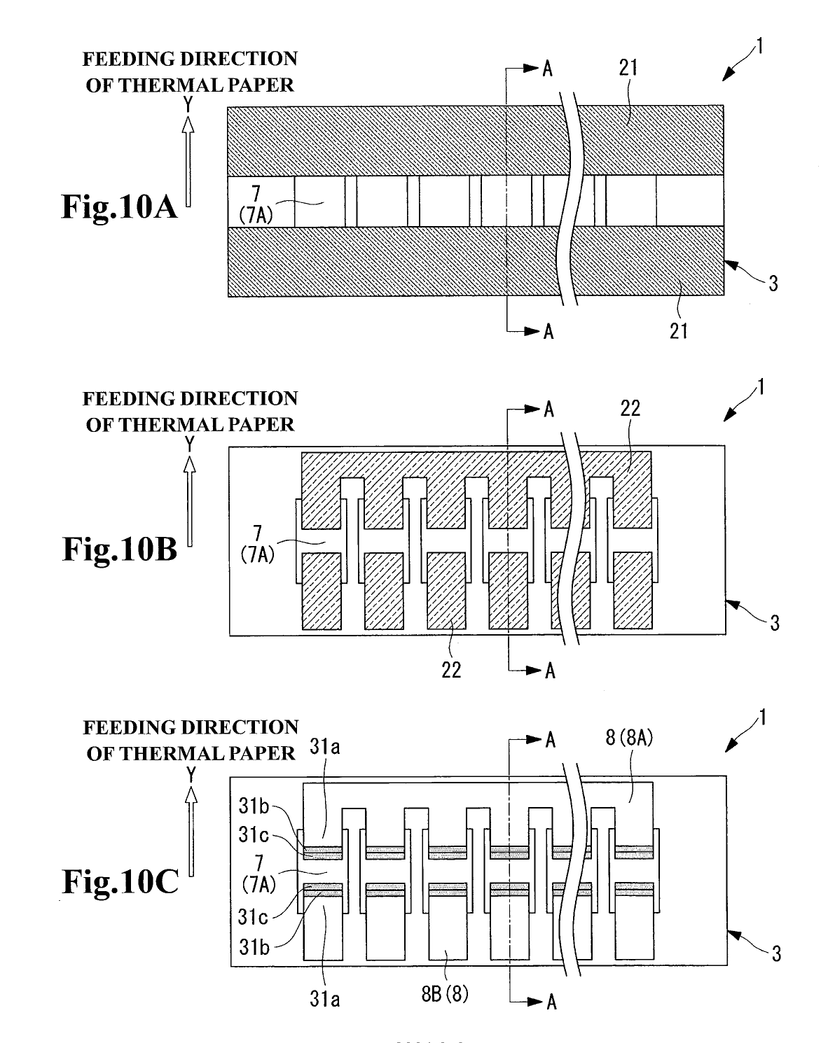

Further, the first and second embodiments adopt the method of providing the inclined surface 30b of the thick electrode portion 30 not only in the longitudinal direction of the heating resistor 7 but also in the direction orthogonal to the longitudinal direction of the heating resistor 7 similarly. However, a method of providing the inclined surface 30b only in the longitudinal direction of the heating resistor 7 may be adopted. In this case, in the first electrode forming step S3, as illustrated in FIG. 10A, the resist masks for thick electrode pattern 21 are formed not only in the region to become the electrode portion 8 but also in other regions.

Further, the resist mask for thin electrode pattern 22 as illustrated in FIG. 10B, that is, similar to the one illustrated in FIG. 8B, is formed. With this, as illustrated in FIG. 10C, the thermal head 1 in which the inclined surface 30b having a tapered shape is provided only in the longitudinal direction of the heating resistor 7 is manufactured. As used herein, the longitudinal direction of the heating resistor 7 refers to a direction along the feeding direction of the thermal paper as illustrated in FIG. 10C, and the lateral direction of the heating resistor 7 refers to a direction orthogonal to the feeding direction of the thermal paper. In this case, at the end portion of the thick electrode portion in the lateral direction of the heating resistor 7, the electrode portion in which the inclined surface having a tapered shape is not provided is provided. In the thin electrode layer, the amount of current flowing in the lateral direction is smaller than that in the longitudinal direction. Further, a load of the platen roller 13 applied in the lateral direction of the protective film 9 is smaller than that in the longitudinal direction. Therefore, regarding the lateral direction of the heating resistor 7 of the thick electrode layer and the thin electrode layer, it is not necessary to use an etchant which is adjusted for forming a gently inclined surface. Accordingly, there is an advantage in that the shape of the resist mask for thick electrode pattern 21 can be made simpler and the manufacturing of the thermal head 1 becomes easier. Further, the electrode portion whose cross section has a substantially right angle can be provided at the end portion of the thick electrode portion in the lateral direction of the heating resistor 7, and hence it is possible to form fine electrode wiring.

Further, the second embodiment adopts the method of performing the resistor forming step S42 after the bonding step S41. However, a method of additionally performing a thinning step between the steps S41 and S42 may be adopted. The thinning step is a step in which, after a thin plate glass is bonded onto the support substrate 3, the thin plate glass is processed so as to have a desired thickness by etching, polishing, or the like. With this, the thermal head 1 including a sufficiently thin upper substrate 60 can be manufactured without using an expensive thin plate glass.

What is claimed is:

1. A thermal head, comprising:
a support substrate;
a heat storage layer formed on a front surface of the support substrate;
a heating resistor provided on a surface of the heat storage layer; and
a pair of electrodes formed on a surface of the heating resistor,
wherein each of the pair of electrodes comprises:
a thick electrode portion including a flat surface having a first thickness and an inclined surface which is provided from the flat surface toward a center of the surface of the heating resistor and whose thickness is gradually reduced toward the center; and
a thin electrode portion which has a second thickness smaller than the first thickness and is formed so as to cover the thick electrode portion, with a distal end position of the thin electrode portion being closer to the center of the surface of the heating resistor with respect to the inclined surface.

2. A thermal head according to claim 1, wherein:
the support substrate includes a concave portion formed in the front surface thereof; and
the concave portion is formed in a region opposed to the heating resistor.

3. A thermal head according to claim 2, wherein:
the concave portion is formed inside a position corresponding to the inclined surface toward the center of the surface of the heating resistor; and
the thin electrode portion is formed in a region opposed to the concave portion.

4. A thermal head according to claim 1, wherein the inclined surface is formed into a tapered shape in which the thickness of the thick electrode portion is gradually reduced at a uniform slope.

5. A thermal head according to claim 4, wherein:
the inclined surface of the thick electrode portion is provided along a feeding direction of thermal paper to be fed by a platen roller, the platen roller being disposed so as to oppose the thermal head; and
an end portion of the thick electrode portion in a direction orthogonal to the feeding direction has a cross section having a substantially right angle.

6. A thermal head according to claim 1, wherein the inclined surface is formed into a stepped shape in which the thickness of the thick electrode portion is reduced in a stepwise manner, and the stepped shape includes steps having a thickness equal to or smaller than the second thickness.

7. A thermal head according to claim 1, wherein the inclined surface and the surface of the heating resistor form an angle of 45° or less.

8. A thermal head according to claim 3, wherein the inclined surface is formed into a tapered shape in which the thickness of the thick electrode portion is gradually reduced at a uniform slope.

9. A thermal head according to claim 8, wherein:
the inclined surface of the thick electrode portion is provided along a feeding direction of thermal paper to be fed by a platen roller, the platen roller being disposed so as to oppose the thermal head; and
an end portion of the thick electrode portion in a direction orthogonal to the feeding direction has a cross section having a substantially right angle.

10. A thermal head according to claim 9, wherein the inclined surface and the surface of the heating resistor form an angle of 45° or less.

11. A thermal head according to claim 3, wherein the inclined surface is formed into a stepped shape in which the thickness of the thick electrode portion is reduced in a stepwise manner, and the stepped shape includes steps having a thickness equal to or smaller than the second thickness.

12. A thermal head according to claim 11, wherein the inclined surface and the surface of the heating resistor form an angle of 45° or less.

13. A thermal printer, comprising the thermal head according to any one of claims 1 to 12.

14. A method of manufacturing a thermal head, comprising:
a heat storage layer forming step of forming a heat storage layer on a front surface of a support substrate;
a resistor forming step of forming a heating resistor on a surface of the heat storage layer formed on the support substrate in the heat storage layer forming step;
a first electrode forming step of forming a pair of thick electrode portions on a surface of the heating resistor formed in the resistor forming step, the pair of thick electrode portions each including a flat surface having a first thickness and an inclined surface which is provided from the flat surface toward a center of the surface of the heating resistor and whose thickness is gradually reduced toward the center; and
a second electrode forming step of forming a pair of thin electrode portions having a second thickness smaller than the first thickness, so as to cover the pair of thick electrode portions, with a distal end position of each of the pair of thin electrode portions being closer to the center of the surface of the heating resistor with respect to the inclined surface.

15. A method of manufacturing a thermal head according to claim 16, further comprising forming a concave portion in the front surface of the support substrate, the concave portion being formed in a region opposed to the heating resistor.
